(19) United States
(12) Patent Application Publication
(10) Pub. No.: US 2005/0150458 A1
(43) Pub. Date: Jul. 14, 2005

(54) Reduced volume reactor

(75) Inventor: Steven T. Fink, Mesa, AZ (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 11/059,626

(22) Filed: Feb. 17, 2005

Related U.S. Application Data
(63) Continuation of application No. PCT/US03/25478, filed on Aug. 14, 2003.
(60) Provisional application No. 60/405,740, filed on Aug. 26, 2002.

(51) Int. Cl. C23C 16/00

(52) U.S. Cl. 118/723 E

(57) ABSTRACT

A plasma processing system and a method for processing a substrate with a plasma processing system. An aspect of the invention provides a plasma processing system that comprises a chamber, including a processing region and an opening, a plasma generating system, constructed and arranged to produce a plasma during a plasma process in the processing region, a chuck, constructed and arranged to support a substrate within the chamber in the processing region, a ring member arranged in the chamber and a moving assembly, constructed and arranged to move the ring member, wherein the ring member is mounted on a periphery of the chuck such that when the substrate is being processed the ring member seals the opening.

This is a continuation of International Application No. PCT/US03/25478, filed on Aug. 14, 2003, which relies upon for priority, and derives the benefit of, U.S. Provisional Patent Application No. 60/405,740, filed Aug. 26, 2002, the entire contents of both of which are incorporated herein by reference in their entireties.

### BACKGROUND OF THE INVENTION

1. Field of the Invention

The invention relates to plasma processing systems, and in particular to a plasma processing system with a reduced volume plasma formation chamber.

2. Description of Related Art

Plasma processing systems are used in the manufacture and processing of semiconductors, integrated circuits, displays, and other devices or materials, to remove material from or to deposit material on a substrate, such as a semiconductor substrate. Due to significant capital and operating expense of such equipment, even small improvements in the equipment or in the methods of using the equipment can lead to significant financial advantage.

### SUMMARY OF THE INVENTION

The present invention provides a plasma processing system that is configured to reduce the processing volume. The plasma processing system comprises a chamber, including a processing region and an opening, a plasma generating system, a chuck, a ring member, and a moving assembly, which is configured to move the ring member. The chuck is designed to support a substrate within the chamber in the processing region. The ring member is mounted on the periphery of the chuck so that when the substrate is being processed in the processing region, the ring member closes or seals the opening.

Another aspect of the invention is to provide a method for processing a substrate with a plasma processing system. The method provides disposing a substrate in a chamber, through an opening, on a movable chuck, moving the chuck to a plasma processing region, moving a ring member, which is mounted on a periphery of the chuck, such that the ring member closes or seals the opening, and forming a plasma within the processing region.

### BRIEF DESCRIPTION OF THE DRAWINGS

FIGS. 1A-1B are schematic representations of a plasma processing chamber assembly according to an embodiment of the present invention;

FIG. 2 is a schematic representation of a plasma processing system according to an embodiment of the present invention; and

FIG. 3 is a schematic plan view representation of a plasma processing system according to an embodiment of the present invention.

### DETAILED DESCRIPTION OF THE EMBODIMENTS OF THE INVENTION

In the following description, in order to facilitate a thorough understanding of the invention and for purposes of explanation and not limitation, specific details are set forth, such as particular geometry of the process chamber, the chuck, the ring member, etc. However, the invention may be practiced in other embodiments that depart from these specific details. The term plasma is used to refer to a mixture of electrons, negative and positive ions, as well as neutral species, such as atoms, molecules and radicals.

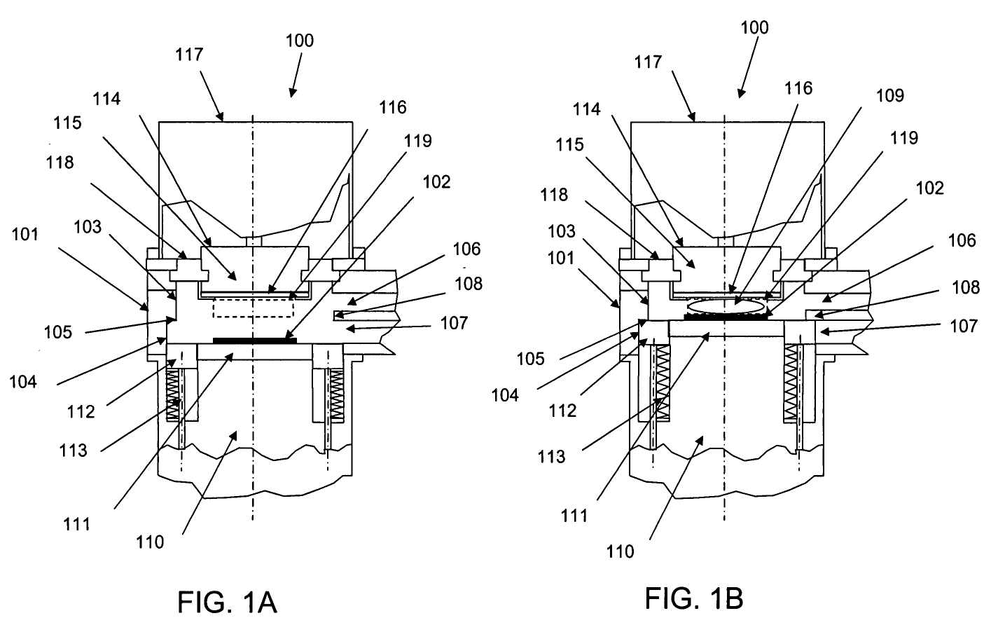

FIGS. 1A and 1B are schematic representations of a plasma processing chamber assembly 100 according to one embodiment of the invention. FIG. 1A illustrates a state in which a substrate can be loaded in or unloaded from plasma processing chamber assembly 100. FIG. 1B illustrates a state in which a substrate is being processed in the processing region. In the following description, those elements of the plasma processing chamber assembly 100 necessary to illustrate the present invention will be put forward, however, it should be understood that other conventional elements can also be present.

Plasma processing chamber assembly 100 comprises a chamber 101 that functions as a vacuum processing chamber adapted to perform plasma etching from and/or material deposition on a substrate 102. Substrate 102 may be, for example, a semiconductor substrate, such as a silicon wafer. Chamber 101 includes upper-sidewall 103 and lower-sidewall 104 that are connected by ledge 105. Chamber 101 further includes openings 106 and 107 that extend radially from the chamber and are separated by member 108. Opening 106 connects chamber 101 to a process vacuum pump (not shown in FIGS. 1A and 1B) and opening 107 may connect chamber 101 to a pre-processing chamber (not shown in FIGS. 1A and 1B). Chamber 101 also defines a plasma processing region 119 in which a plasma 109 can be generated. For example, chamber 101 can be fabricated from the stacking of a plurality of flat plates, wherein the chamber 101, the chamber to which the access to the process vacuum pump is gained, and the pre-processing chamber (or transfer chamber) are the same. Alternatively, each chamber is fabricated independent of one another and coupled to one another. In the latter configuration, a single opening in chamber 101 can be fabricated, wherein the two openings are formed when coupling the chamber 101 to the additional chambers. Alternatively, in the latter configuration, two openings can be fabricated within the chamber 101.

Plasma processing chamber assembly 100 further includes a chuck assembly 110 that comprises a chuck or electrode 111. Chuck assembly 110 is constructed and arranged to support substrate 102 and can move vertically within chamber 101. Chuck assembly 110 can also be connected to a Radio Frequency (RF) power supply (not shown) in order to couple electrical bias to the electrode 111, such as for forming plasma 109 and/or attracting ions in plasma 109.

Plasma processing chamber assembly 100 also includes a ring member 112 that is mounted on a periphery of the chuck assembly 110. In fact, ring member 112 can be fixed to chuck assembly 110. Ring member 112 can be slidable against a wall of chamber 101, as shown in FIGS. 1A-1B, wherein, desirably, an appropriate clearance gap is present between the outer radius of the ring member 112 and the inner radius of lower side-wall 104. In this particular embodiment, ring member 112 is slidable against lower-sidewall 104 of chamber 101 and has a cylindrical form. However, ring member 112 can also have a polygonal form or an elliptical form. Also, ring member 112 is securely connected to a moving assembly 113, which may comprise a bellows assembly, so that ring member 112 can move vertically, while isolating the internal components of the moving assembly 113 from vacuum. Alternately, the moving assembly 113 can be securely connected to the chuck assembly 110. Ring member 112 can be fabricated as part of the chuck assembly 110 (i.e. fabricated from a single piece of material), or it can be attached using a weld joint. Alternately, ring member 112 can be coupled to the chuck assembly 110 using fasteners, such as bolts, and it can further utilize a sealing member to seal the ring member 112 with the chuck assembly 110 and optionally an electrical contact gasket such as Spirashield to provide good electrical contact. Once ring member 112 is fixedly attached to the chuck assembly 110, a mechanical drive system (not shown) can be utilized to actuate moving assembly 113 and, therefore, provide vertical movement for the ring member 112 and the chuck assembly 110.

Plasma processing chamber assembly 100 further comprises a plasma generating system 114, which includes an electrode assembly 115. Electrode assembly 115 comprises an upper electrode 116 arranged within chamber 101 and facing chuck assembly 110 and ring member 112. Upper electrode 115 may have a plurality of holes, i.e. a shower-head, for process gas injection (not shown). Electrode assembly 115 may be electrically connected to a RF power supply system (not shown). The RF power supply may have coupled thereto an associated impedance match network 117 to match the impedance of electrode assembly 115 and the associated plasma 109 to the source impedance of the RF power supply system, thereby improving the percentage of power that may be delivered by the RF power supply to electrode assembly 115 and associated plasma 109.

Plasma processing chamber assembly 100 also includes an insulator 118 arranged at the periphery of electrode assembly 115 and insulates chamber 101 from electrode assembly 115. Also, while not depicted in FIGS. 1A-1B, plasma processing system 100 may further comprise a gas source configured to introduce gases into chamber 101 in order to create plasma 109.

As mentioned previously, FIG. 1B represents plasma processing chamber assembly 100 in a configuration where a substrate is being processed in processing region 119. In this configuration, chuck assembly 110 has been raised to its process position, after substrate 102 was disposed on chuck electrode 111 through opening 107. Also, in this configuration, ring member 112 abuts ledge 105 and member 108, and closes or forms a vacuum seal with the respective contact surface, hence closing or sealing opening 107. Therefore, in this configuration, ring member 112 can serve as a sealing slot valve (if ring member 112 seals against ledge 105 and member 108) and confines a small volume area in chamber 101. Also, as the volume of chamber 101 is reduced, chamber 101 can be fabricated from standard plate-stocks instead of large billets and may use smaller chamber liners to cover the walls of chamber 101.

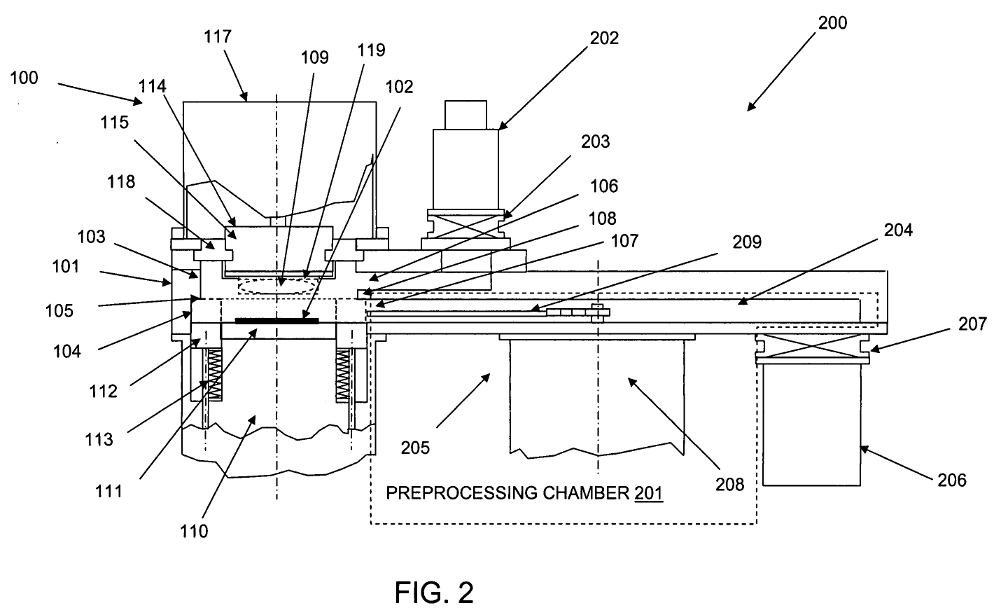

FIG. 2 is a schematic representation of a plasma processing system 200 according to an embodiment of the invention. Plasma processing system 200 comprises a preprocessing chamber 201, a process vacuum pump 202, a valve 203, and a plasma processing chamber assembly 100 similar to the chamber assembly described above in FIGS. 1A-1B. In this embodiment, preprocessing chamber 201 is in direct communication with chamber 101 through opening 107, and the process vacuum pump 202 gains access to chamber 101 through opening 106.

Preprocessing chamber 201 comprises a chamber 204 and a robot 205. A robot vacuum pump 206 is in communication with chamber 204 through a valve 207. Robot 205 includes a robot mechanism 208 and a robot arm 209, which is constructed and arranged to dispose substrate 102 in chamber 101 through opening 107. Robot 205 may be in operative communication with chamber 101, chuck assembly 110, and moving assembly 113 for transporting substrate 102 in chamber 101.

FIG. 2 represents the plasma processing system 200 in a configuration where substrate 102 can be loaded in or unloaded from chamber 101. In such a configuration, ring member 112 and chuck assembly 110 are stationed in a lower position as also shown in FIG. 1A. However, when substrate 102 has been disposed in chamber 101, chuck assembly 110 and ring member 112 can be moved to a position, indicated by the dotted lines, where substrate 102 can be processed by plasma 109 in processing region 119. In this position, ring member 112 closes or seals opening 107 and abuts on to ledge 105 and member 108.

Process vacuum pump 202 is in direct communication with chamber 101 through valve 203 and opening 106. Process vacuum pump 202 and valve 203 are shown mounted to the top of preprocessing chamber 201 for clarity, but could be mounted from a middle surface of chamber 101 and suspended below the structure of plasma processing system 200 shown in FIG. 2. Finally, when substrate 102 is being processed, the resulting small process chamber 101 is pumped from the top by process vacuum pump 202. Opening 106 defines a passage to an inlet of process vacuum pump 202 which is disposed in a plane parallel to substrate 102 and proximate to processing region 119. Alternately, one or more additional vacuum pumps, with or without a valve, can be coupled to chamber 101 as is process vacuum pump 202.

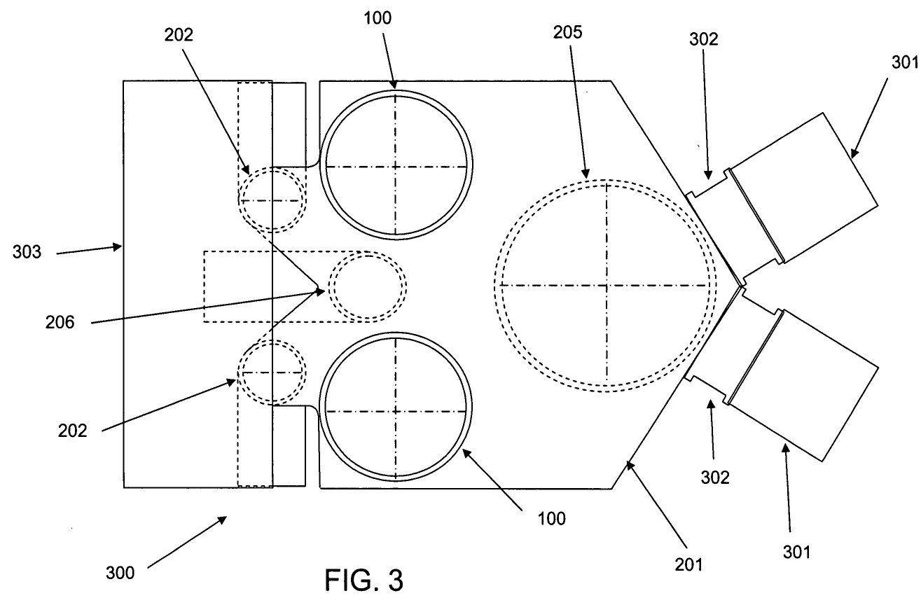

FIG. 3 is a schematic plan view representation of a plasma processing system 300 according to an embodiment of the present invention. Main components are identified in this possible arrangement of sub-assemblies. It is understood that an infinite number of possible arrangements are possible. Additionally, it is noted that less than two or more than two processing stations could be used in a reactor design. This invention does not limit placement or number of sub-assemblies present.

Plasma processing system 300 comprises pre-processing chamber 201, process vacuum pump 202, cassette 301, gate valve 302, gas panel 303 and plasma processing chamber assemblies 100, which are similar to those described above in FIGS. 1A-1B.

Cassette 301 is constructed and arranged to house a plurality of substrates and is in communication with pre-processing chamber 201 through gate valve 302. Pre-processing chamber 201 comprises robot 205 and is in communication with robot vacuum pump 206. Gas panel 303 is configured to introduce gases into chamber 101 (not shown) of plasma processing system 300.

In this embodiment, robot 205 can be in operative communication with either chamber assembly 100 and with either cassette 301 and can unload a substrate from cassette 301 and dispose the substrate in chamber assembly 100.

While a detailed description of presently preferred embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

1. A plasma processing system comprising:
a chamber, including a processing region and an opening;
a plasma generating system constructed and arranged to produce a plasma during a plasma process in the processing region;
a chuck, constructed and arranged to support a substrate within the chamber in the processing region;
a ring member arranged in the chamber; and
a moving assembly constructed and arranged to move the ring member;
wherein:
the ring member is mounted on a periphery of the chuck such that when the substrate is being processed the ring member closes the opening.

2. The plasma processing system as recited in claim 1, wherein the chuck is movable from a first position to a second position such that when the chuck is in the first position the substrate is loaded into the chamber and when the chuck is in the second position the substrate is being processed in the processing region.

3. The plasma processing system as recited in claim 1 wherein the ring member is slidable against a wall of the chamber.

4. The plasma processing system as recited in claim 1 further comprising a ledge arranged in the chamber such that the ring member abuts on to the ledge when the ring member closes the opening.

5. The plasma processing system as recited in claim 1 wherein the moving assembly comprises a bellows assembly.

6. The plasma processing system as recited in claim 1 wherein the ring member has a shape selected from the group consisting of a cylindrical form, a polygonal form and an elliptical form.

7. The plasma processing system as recited in claim 1 wherein the plasma generating system comprises an electrode connected to an RF power supply.

8. The plasma processing system as recited in claim 7 wherein the electrode comprises a plurality of holes for process gas injection.

9. The plasma processing system as recited in claim 1 further comprising a gas source configured to introduce gases into the chamber.

10. The plasma processing system as recited in claim 1 wherein the chuck is connected to an RF power supply.

11. The plasma processing system as recited in claim 1 further comprising a vacuum pump in communication with the chamber and constructed and arranged to control a pressure within the chamber.

12. The plasma processing system as recited in claim 11 wherein the vacuum pump has an inlet which communicates with the processing region through a passage in the chamber disposed in a plane parallel to a substrate or the chuck and proximate to the processing region.

13. The plasma processing system as recited in claim 1 wherein the chamber is constructed with metal plate stocks.

14. The plasma processing system as recited in claim 1 further comprising:
a preprocessing chamber; and
a robot disposed in the preprocessing chamber, the robot being constructed and arranged to transport a substrate from the preprocessing chamber to the chuck through the opening.

15. The plasma processing system as recited in claim 1 further comprising:
a preprocessing chamber;
a vacuum pump in communication with the preprocessing chamber;
a gate valve; and
a cassette for housing a substrate, the preprocessing chamber comprising a robot mechanism, wherein the cassette is in communication with the preprocessing chamber through the gate valve and the preprocessing chamber is in communication with the chamber through the opening.

16. The plasma processing system as recited in claim 1 wherein the ring member is fixed to the chuck and the moving member moves both the ring member and the chuck.

17. A method for processing a substrate with a plasma processing system, the method comprising:
disposing a substrate in a chamber, through an opening, on a movable chuck;
moving the chuck to form a plasma processing region;
moving a ring member, which is mounted on a periphery of the chuck, such that the ring member closes the opening; and
forming a plasma within the processing region.

18. The method for processing a substrate as recited in claim 17 wherein the ring member is moved by a moving assembly comprising a bellows assembly.

19. The method for processing a substrate as recited in claim 17 further comprising abutting the ring member on to a ledge to close the opening.

20. The method for processing a substrate as recited in claim 17 wherein the ring member is slidable against a wall of the chamber.

21. The method for processing a substrate as recited in claim 17 wherein the plasma is formed by a plasma generating system that comprises an electrode connected to an RF power supply.

22. The method for processing a substrate as recited in claim 17 further comprising injecting process gas through a plurality of holes in the electrode.

23. The method for processing a substrate as recited in claim 17 further comprising pumping material from the chamber and controlling a pressure within the chamber.

24. The method for processing a substrate as recited in claim 23, wherein the pumping occurs along a plane parallel to a substrate in the chamber and proximate to the plasma processing region.
